(19) United States
(12) Patent Application Publication
(10) Pub. No.: US 2024/0006438 A1
(43) Pub. Date: Jan. 4, 2024

(54) IMAGING DEVICE

(71) Applicant: SONY SEMICONDUCTOR SOLUTIONS CORPORATION, Kanagawa (JP)

(72) Inventors: Itaru OSHIYAMA, Kanagawa (JP); Shigehiro IKEHARA, Kanagawa (JP)

(73) Assignee: SONY SEMICONDUCTOR SOLUTIONS CORPORATION, Kanagawa (JP)

(21) Appl. No.: 18/253,642

(22) PCT Filed: Nov. 9, 2021
(86) PCT No.: PCT/JP2021/041062

§ 371 Date: May 19, 2023

(30) Foreign Application Priority Data
Dec. 1, 2020 (JP) 2020-199693

(51) Int. Cl. H01L 27/146

(52) U.S. Cl. CPC H01L 27/14623; H01L 27/14645; H01L 27/14621; H01L 27/14627; H01L 27/14685

(57) ABSTRACT

There is provided an imaging device capable of reducing sensitivity unevenness of a pixel located near a boundary between a pixel section and an optical black section. An imaging device includes a semiconductor layer, a pixel section that is provided in the semiconductor layer and receives light from an object, an optical black section that is provided in the semiconductor layer and includes a light shielding film that shields light, a color filter provided on one surface side of the semiconductor layer, and a low refractive index material that is provided on one surface side of the semiconductor layer and has a refractive index lower than a refractive index of the color filter. The pixel section and the optical black section are adjacent to each other. The low refractive index material is disposed between filter components of the color filter in the pixel section, and is not disposed in the optical black section.

### TECHNICAL FIELD

The present disclosure relates to an imaging device.

### BACKGROUND ART

An imaging device including a pixel section that receives light from a subject and a light shielding section that shields light from the subject is known (see, for example, Patent Document 1).

### CITATION LIST

### Patent Document

Patent Document 1: International Publication No. 2013/054535

### SUMMARY OF THE INVENTION

### Problems to be Solved by the Invention

A light shielding film is disposed on the light shielding section. A step is generated between the pixel section and the light shielding section due to the thickness of the light shielding film or the thickness of a film covering the light shielding film. Due to this step, the film thickness of a color filter of a pixel located near a boundary with the light shielding section in the pixel section is more likely to be non-uniform than the film thickness of the color filter of other pixels away from the boundary. The non-uniformity of the film thickness of the color filter causes sensitivity unevenness (variation in sensitivity) of the pixel. Furthermore, an on-chip lens of the light shielding section is located on the upper side of the step (that is, the side close to a light source) with respect to an on-chip lens of the pixel section. Therefore, there is a possibility that a part of light obliquely incident on the on-chip lens or the color filter of the light shielding section passes through the on-chip lens and the color filter of the light shielding section (hereinafter, also referred to as an optical black section) and is incident on the on-chip lens and the color filter of the pixel located near the boundary. As a result, the pixel located near the boundary tends to cause the sensitivity unevenness more easily than other pixels away from the boundary.

The present disclosure has been made in view of such circumstances, and an object of the present disclosure is to provide an imaging device capable of reducing sensitivity unevenness of the pixel located near a boundary between a pixel section and an optical black section.

### Solutions to Problems

An imaging device according to one aspect of the present disclosure includes a semiconductor layer, a pixel section that is provided in the semiconductor layer and receives light from an object, an optical black section that is provided in the semiconductor layer and includes a light shielding film that shields light, a color filter provided on one surface side of the semiconductor layer, and a low refractive index material that is provided on one surface side of the semiconductor layer and has a refractive index lower than a refractive index of the color filter. The pixel section and the optical black section are adjacent to each other. The low refractive index material is disposed between filter components of the color filter in the pixel section, and is not disposed in the optical black section.

Thus, as compared with a case where the low refractive index material is disposed on the light shielding film, the imaging device can reduce a step near a boundary between the pixel section and the optical black section. As a result, the imaging device can make a film thickness of the color filter located near the boundary as uniform as possible. Furthermore, by reducing the step described above, the imaging device can suppress light transmitted through an on-chip lens and the color filter of the optical black section from entering the on-chip lens and the color filter of a pixel located near the boundary. Therefore, the imaging device can reduce sensitivity unevenness of the pixel located near the boundary.

An imaging device according to another aspect of the present disclosure includes a semiconductor layer, a pixel section that is provided in the semiconductor layer and receives light from an object, an optical black section that is provided in the semiconductor layer and includes a light shielding film that shields light, a color filter provided on one surface side of the semiconductor layer, and a low refractive index material that is provided on one surface side of the semiconductor layer and has a refractive index lower than a refractive index of the color filter. The pixel section and the optical black section are adjacent to each other. The low refractive index material includes a first area disposed between the filter components of the color filters in the pixel section and a second area disposed between the light shielding film and the color filter in the optical black section. A thickness of a part of the second area adjacent to the pixel section is thinner than a thickness of the first area.

Thus, as compared with a case where the low refractive index material is disposed on the light shielding film so as to be thick, the imaging device can reduce a step near a boundary between the pixel section and the optical black section. As a result, the imaging device can make a film thickness of the color filter located near the boundary as uniform as possible. Furthermore, by reducing the step described above, the imaging device can suppress light transmitted through an on-chip lens and the color filter of the optical black section from entering the on-chip lens and the color filter of a pixel located near the boundary. Therefore, the imaging device can reduce sensitivity unevenness of the pixel located near the boundary.

### BRIEF DESCRIPTION OF DRAWINGS

FIG. 1 is a diagram depicting a configuration example of an imaging device according to a first embodiment of the present disclosure.

FIG. 2 is a sectional view depicting a configuration example of a pixel region, which is a part of the imaging device according to the first embodiment of the present disclosure.

FIG. 3 is a sectional view depicting a method of manufacturing the imaging device according to the first embodiment of the present disclosure step by step.

FIG. 4 is a sectional view depicting the method of manufacturing the imaging device according to the first embodiment of the present disclosure step by step.

FIG. 5 is a sectional view depicting the method of manufacturing the imaging device according to the first embodiment of the present disclosure step by step.

FIG. 6 is a sectional view depicting the method of manufacturing the imaging device according to the first embodiment of the present disclosure step by step.

FIG. 7 is a sectional view depicting the method of manufacturing the imaging device according to the first embodiment of the present disclosure step by step.

FIG. 8 is a sectional view depicting the method of manufacturing the imaging device according to the first embodiment of the present disclosure step by step.

FIG. 9 is a sectional view depicting the method of manufacturing the imaging device according to the first embodiment of the present disclosure step by step.

FIG. 10 is a sectional view depicting the method of manufacturing the imaging device according to the first embodiment of the present disclosure step by step.

FIG. 11 is a sectional view depicting the method of manufacturing the imaging device according to the first embodiment of the present disclosure step by step.

FIG. 12 is a sectional view depicting the method of manufacturing the imaging device according to the first embodiment of the present disclosure step by step.

FIG. 13 is a sectional view depicting a configuration of an imaging device according to a first modification of the first embodiment of the present disclosure.

FIG. 14 is a sectional view depicting a configuration of an imaging device according to a second modification of the first embodiment of the present disclosure.

FIG. 15 is a sectional view depicting a configuration example of an imaging device according to a third modification of the first embodiment of the present disclosure.

FIG. 16 is a sectional view depicting a configuration example of an imaging device according to a second embodiment of the present disclosure.

### MODE FOR CARRYING OUT THE INVENTION

Hereinafter, embodiments of the present disclosure will be described with reference to the drawings. In the illustration of the drawings referred to in the following description, the same or similar parts are denoted by the same or similar reference signs. It should be noted that the drawings are schematic, and a relationship between a thickness and a planar dimension, a ratio of the thicknesses between layers, and the like are different from actual ones. Therefore, specific thicknesses and dimensions should be determined in consideration of the following description. Furthermore, it is needless to say that the drawings include parts having different dimensional relationships and ratios.

Definition of directions such as upward and downward directions in the following description is merely the definition for convenience of description, and does not limit the technical idea of the present disclosure. For example, it is a matter of course that when an object is observed by rotating the object by 90°, the up and down are converted into and read as left and right, and when the object is observed by rotating the object by 180°, the up and down are inverted and read.

### First Embodiment

(Overall Configuration)

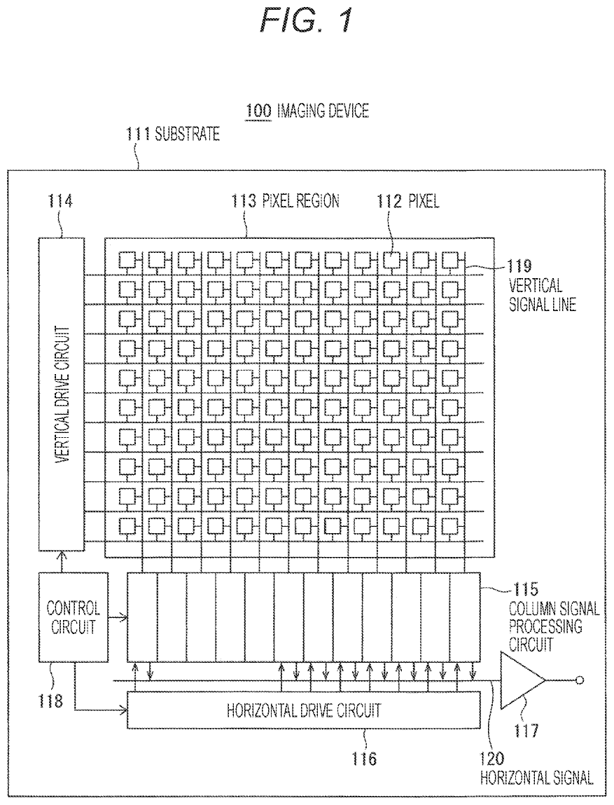

FIG. 1 is a diagram depicting a configuration example of an imaging device 100 according to a first embodiment of the present disclosure. The imaging device 100 shown in FIG. 1 includes a substrate 111 including silicon, a pixel region (so-called imaging region) 113 having a plurality of pixels 112 aligned on the substrate 111, and a peripheral circuit unit. The peripheral circuit unit includes a vertical drive circuit 114, a column signal processing circuit 115, a horizontal drive circuit 116, an output circuit 117, and a control circuit 118.

The pixel region 113 includes the plurality of pixels 112 regularly arranged in a two-dimensional array. The pixel region 113 includes a pixel section that receives incident light, amplifies signal charges generated by photoelectric conversion, and reads the amplified signal charges to the column signal processing circuit 115, and an optical black section (hereinafter, an OPB section) that outputs optical black serving as a reference of a black level. The OPB section may be referred to as a light shielding section. The OPB section is provided in a region adjacent to the pixel section, such as an outer periphery of the pixel section.

The pixel 112 includes, for example, a photoelectric conversion element (not shown) which is a photodiode and a plurality of pixel transistors (so-called MOS transistors). The plurality of pixels 112 is regularly arranged in a two-dimensional array on the substrate 111. The plurality of pixel transistors can include three transistors of a transfer transistor, a reset transistor, and an amplification transistor. The plurality of pixel transistors can include four transistors by adding a selection transistor to the above three transistors. The pixels 112 can have a shared pixel structure. The shared pixel structure includes a plurality of photodiodes, a plurality of transfer transistors, one shared floating diffusion, and each one of other shared pixel transistors.

The control circuit 118 generates a clock signal and a control signal, which are references for operations of the vertical drive circuit 114, the column signal processing circuit 115, and the horizontal drive circuit 116, on the basis of a vertical synchronization signal, a horizontal synchronization signal, and a master clock. The control circuit 118 controls the vertical drive circuit 114, the column signal processing circuit 115, and the horizontal drive circuit 116 by using the clock signal and the control signal.

The vertical drive circuit 114 includes, for example, a shift resistor, and selectively scans the pixels 112 sequentially in a vertical direction row by row. The vertical drive circuit 114 supplies a pixel signal based on a signal charge generated in accordance with a light receiving amount in the photoelectric conversion element of the pixels 112 to the column signal processing circuit 115 through a vertical signal line 119.

The column signal processing circuit 115 is disposed for each column of the pixels 112, for example. The column signal processing circuit 115 performs signal processing such as noise removal and signal amplification on the signals output from the pixels 112 of one row for each pixel column by a signal from the OPB section. A horizontal selection switch (not shown) is provided between an output stage of the column signal processing circuit 115 and the horizontal signal line 120.

The horizontal drive circuit 116 includes, for example, a shift register. The horizontal drive circuit 116 sequentially selects each of the column signal processing circuits 115 by sequentially outputting horizontal scanning pulses, and causes each of the column signal processing circuits 115 to output a pixel signal to the horizontal signal line 120.

The output circuit 117 performs signal processing on the pixel signals sequentially supplied from each of the column signal processing circuits 115 via the horizontal signal line 120, and outputs the processed pixel signals to an external device (not shown).

The output circuit 117 performs signal processing on the signals sequentially supplied from each of the column signal processing circuits 115 through the horizontal signal line 120, and outputs the signals. For example, in some cases, the output circuit 117 performs only buffering, and in other cases, performs various digital signal processing or the like such as black level adjustment, and column variation correction.

(Configuration Example of Pixel Region)

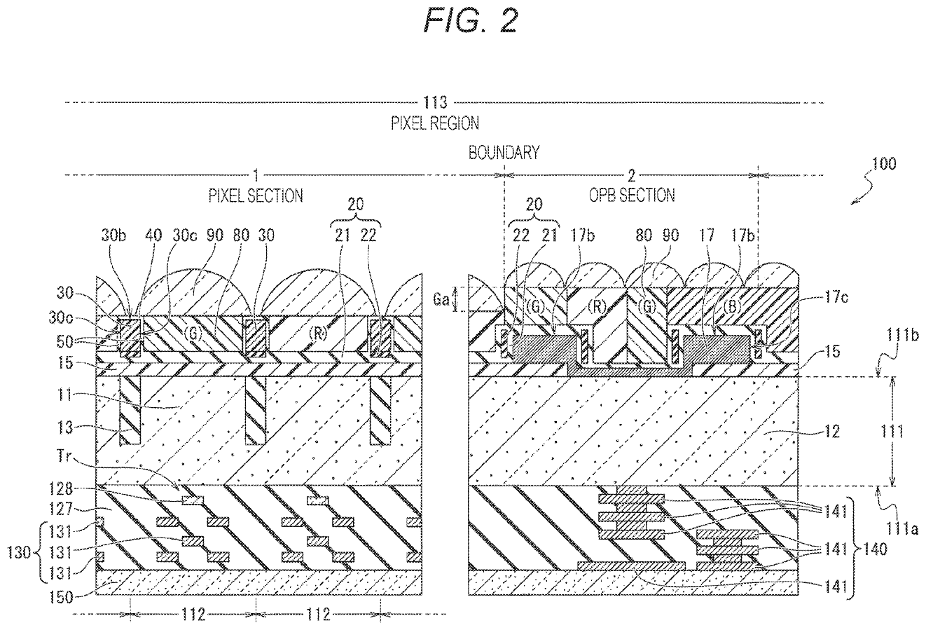

Next, details of the imaging device 100 will be described with reference to FIG. 2. FIG. 2 is a sectional view depicting a configuration example of the pixel region 113, which is a part of the imaging device 100 according to the first embodiment of the present disclosure. The imaging device 100 is, for example, a back-illuminated solid-state imaging device, includes, as shown in FIG. 2, the substrate 111 (an example of a “semiconductor layer” of the present disclosure), includes an interlayer insulating film 127, wiring layers 130 and 140, and a support substrate 150 which are provided on a front surface 111a (in FIG. 2, a lower surface) of the substrate 111, and includes insulating films 15, 20, 40, and 50, a light shielding film 17, a low refractive index material 30, a color filter 80, and a microlens 90 which are provided on a back surface 111b (in FIG. 2, an upper surface) of the substrate 111.

The substrate 111 includes, for example, silicon. The substrate 111 is provided with the plurality of pixels 112 in a two-dimensional matrix (see FIG. 1). Each of the plurality of pixels 112 includes a photoelectric conversion element 11 and a plurality of pixel transistors Tr. The photoelectric conversion element 11 is, for example, a photodiode, and signal charges corresponding to the amount of received incident light are generated and accumulated. The pixel transistor Tr includes a source-drain region provided on the front surface side of the substrate 111 and a gate electrode 128 provided on the front surface of the substrate 111 via a gate insulating film.

In addition, the substrate 111 is provided with an element isolation layer 13 that electrically isolates adjacent pixels 112 from each other. For example, the element isolation layer 13 includes a high-concentration impurity layer provided on the substrate 111, a silicon oxide film embedded in a trench provided on the substrate 111, or the like. The element isolation layer 13 is formed, for example, from the back surface 111b of the substrate 111 to an intermediate position between the back surface 111b and the front surface 111a (that is, an intermediate position in a depth direction of the substrate 111).

The interlayer insulating film 127 is provided continuously over the entire pixel region 113 including a pixel section 1 and an OPB section 2 on the front surface 111a of the substrate 111. The interlayer insulating film 127 includes, for example, a silicon oxide film or a laminated film of a silicon oxide film and a silicon nitride film.

The wiring layer 130 is provided in the pixel section 1 and includes a plurality of wirings 131 laminated with the interlayer insulating film 127 interposed therebetween. The pixel transistor Tr constituting the pixels 112 is driven via the plurality of wirings 131 included in the wiring layer 130. Furthermore, the signal charge generated by the photoelectric conversion element 11 of the pixel section 1 is output via the plurality of wirings 131 included in the wiring layer 130.

The wiring layer 140 is provided in the OPB section 2 and includes a plurality of wirings 141 laminated with the interlayer insulating film 127 interposed therebetween. The signal charge serving as the reference of the black level generated by the photoelectric conversion element 12 of the OPB section 2 is output via the plurality of wirings 141 included in the wiring layer 140.

The plurality of wirings 131 included in the wiring layer 130 and the plurality of wirings 141 included in the wiring layer 140 include, for example, aluminum (Al), an Al alloy containing Al as a main component, copper (Cu), or a Cu alloy containing Cu as a main component.

The support substrate 150 is provided on the front surface 111a of the substrate 111 with the interlayer insulating film 127 interposed therebetween. The support substrate 150 is configured to secure a strength of the substrate 111 at a manufacturing stage. The support substrate 150 includes, for example, silicon. Note that, in the first embodiment of the present disclosure, a part of the peripheral circuit unit may be provided on the support substrate 150.

The insulating film 15 is provided on the back surface 111b (in FIG. 2, the upper surface) of the substrate 111 in each of the pixel section 1 and the OPB section 2. The insulating film 15 is a protective film for protecting the back surface 111b of the substrate 111. The insulating film 15 is, for example, a silicon oxide film.

An insulating film 20 (an example of a “first protective film” of the present disclosure) is provided on the insulating film 15. The insulating film 20 includes, for example, a laminated layer portion including a silicon oxide film 21 and a silicon nitride film 22, and a single layer portion including only the silicon oxide film 21. For example, in the pixel section 1, a single layer part of the insulating film 20 is disposed in an upper part of the pixels 112, and a laminated layer part of the insulating film 20 is disposed above the element isolation layer 13. In addition, in the OPB section 2, the insulating film 20 is disposed between the color filter 80 and the light shielding film 17. The insulating film 20 covers the light shielding film 17. For example, the light shielding film 17 has an upper surface 17b facing the microlens 90 with the color filter 80 interposed therebetween, and a side surface 17c orthogonal to the upper surface 17b. The upper surface 17b of the light shielding film 17 is covered with the single layer part of the insulating film 20, and the side surface 17c of the light shielding film 17 is covered with the laminated layer part of the insulating film 20.

As a result, in the pixel section 1, the insulating film 20 functions as a protective film that prevents the color filter 80 and the substrate 111 from directly contacting with each other. In addition, in the OPB section 2, the insulating film 20 functions as a protective film that prevents the color filter 80 and the light shielding film 17 from directly contacting with each other. Furthermore, the insulating film 20 also functions as a protective film for protecting the back surface 111b of the substrate 111 and the light shielding film 17 from an etching atmosphere or the like when the low refractive index material 30, the color filter 80, and the like are formed.

In the OPB section 2, the insulating film 15 is provided with an opening having the back surface 111b of the substrate 111 as a bottom surface. The light shielding film 17 is provided on the insulating film 15 so as to fill the opening. Thus, the light shielding film 17 covers the back surface 111b of the substrate 111 and is electrically connected to the back surface 111b of the substrate 111. The light shielding film 17 includes, for example, tungsten (W). Note that the material constituting the light shielding film 17 is not limited to W. The light shielding film 17 may include any metal material that shields visible light, for example, copper (Cu). Furthermore, the light shielding film 17 is not limited to a single layer film, and may be a laminated film in which a plurality of layers is laminated.

The color filter 80 is provided on the back surface 111b of the substrate 111 with the insulating film 20 interposed therebetween. The color filter 80 has a plurality of filter components, and for example, has a first filter component, a second filter component, and a third filter component for each pixel 112. For example, the first filter component, the second filter component, and the third filter component are a green filter component (G), a red filter component (R), and a blue filter component (B), respectively. In addition, the first filter component, the second filter component, and the third filter component are not limited to the above filter components, and may be any color filter components. In addition, at least one or more of the first filter component, the second filter component, or the third filter component may be other than a color filter component, and may be, for example, a filter component that attenuates visible light, such as a transparent resin that transmits visible light or an ND filter formed by adding a carbon black dye to a transparent resin.

In the imaging device 100 according to the first embodiment, the low refractive index material 30 is provided in the pixel section 1 and is not provided in the OPB section 2. In the pixel section 1, the low refractive index material 30 is disposed between the filter components of the color filters 80. The low refractive index material 30 includes a material having a refractive index lower than a refractive index of the color filter 80. As a material having a refractive index lower than the refractive index of the color filter 80, a silicone resin is exemplified. The refractive index of the low refractive index material 30 is, for example, 1.0 or more and 1.6 or less.

Since the low refractive index material 30 has a refractive index lower than the refractive index of the color filter 80, light to be incident from one filter component (for example, the green filter component (G)) to the other filter component (for example, the red filter component (R)) adjacent to the one filter component can be totally reflected toward the one filter component.

The low refractive index material 30 has an upper surface 30b located near the microlens 90 and a side surface 30c orthogonal to the upper surface 30b. The upper surface 30b of the low refractive index material 30 is covered with an insulating film 40. The insulating film functions as a protective film that protects the upper surface 30b of the low refractive index material 30. The insulating film 40 includes, for example, a silicon oxide film.

The side surface 30c of the low refractive index material 30 is covered with an insulating film 50 (an example of a “second protective film” of the present disclosure). The insulating film 50 is disposed between the low refractive index material 30 and the color filter Specifically, the insulating film 50 is disposed between the low refractive index material 30 and each filter component (for example, the green filter component (G), the red filter component (R), and the blue filter component (B)) of the color filter 80. The insulating film 50 protects the side surface 30c of the low refractive index material 30 and functions as a protective film for preventing the low refractive index material 30 and the color filter 80 from directly contacting with each other. The insulating film 50 includes, for example, a silicon oxide film.

The microlens 90 is provided on the color filter 80. The microlens 90 is formed with, for example, an organic material such as resin. Light incident from the back surface 111b of the substrate 111 is condensed by the microlens 90 and is incident on the color filter 80. In the color filter 80, light having a desired wavelength is transmitted, and the transmitted light is incident on the photoelectric conversion element 11 in the substrate 111.

As shown in FIG. 2, the pixel section 1 and the OPB section 2 are disposed adjacent to each other. In the imaging device 100 according to the first embodiment, the low refractive index material 30 is disposed in the pixel section 1, whereas the low refractive index material 30 is not disposed in the OPB section 2. Therefore, for example, as compared with a case where the low refractive index material 30 is disposed on the light shielding film 17, the imaging device 100 can reduce a step Ga near the boundary between the pixel section 1 and the OPB section 2.

(Manufacturing Method)

Next, a method of manufacturing the imaging device 100 according to the first embodiment of the present disclosure is described. The imaging device 100 is manufactured by using various devices such as a film forming device (including a chemical vapor deposition (CVD) device, a sputtering device, and a thermal oxidation device), an exposure device, an etching device, a chemical mechanical polishing (CMP) device, and a bonding device. Hereinafter, these devices are collectively referred to as manufacturing devices. The pixel region of the imaging device 100 can be manufactured by a manufacturing method described below.

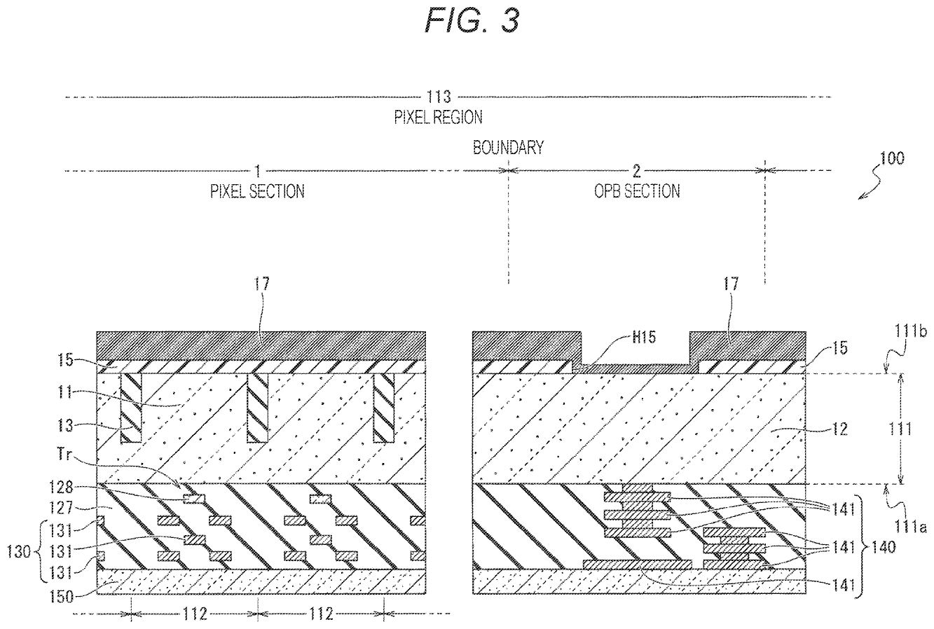

FIGS. 3 to 12 are sectional views each depicting the method of manufacturing the imaging device 100 according to the first embodiment of the present disclosure step by step. Note that, in FIG. 3, steps up to a step of forming the insulating film 15 on the back surface 111b of the substrate 111 and forming an opening H15 in the insulating film 15 are manufactured by a well-known method, and thus the description of the steps will be omitted. In FIG. 3, the manufacturing device forms the light shielding film 17 on the insulating film 15 in which the opening H15 is formed. For example, the light shielding film 17 is a thin film of tungsten (W), and a method of forming the light shielding film 17 is a vapor deposition or sputtering method.

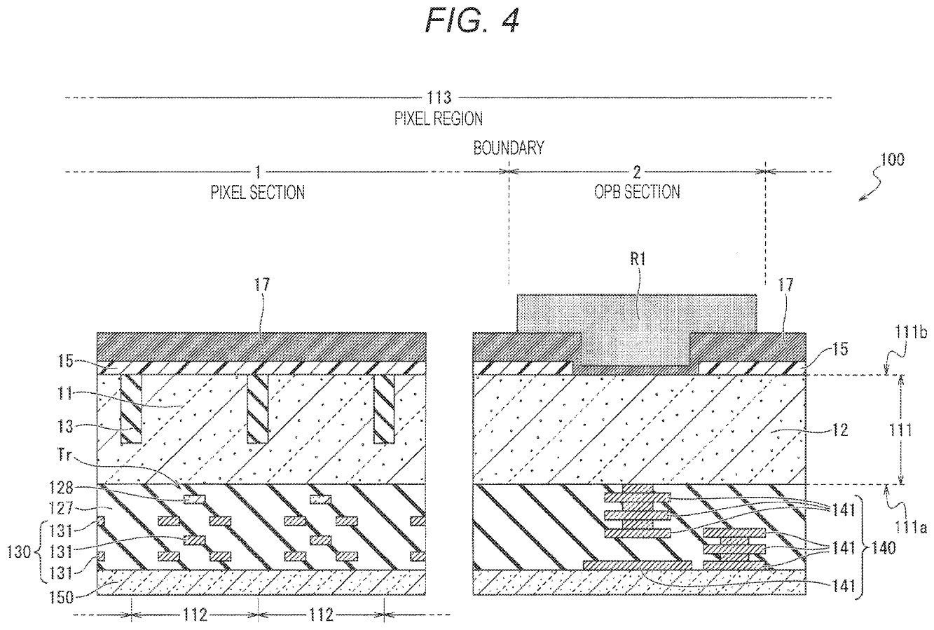

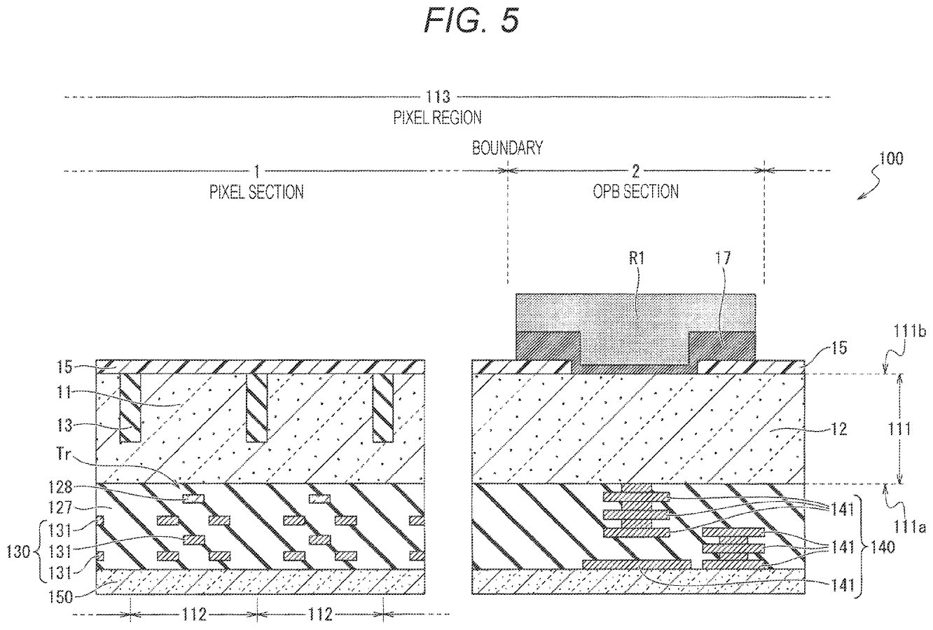

Next, as shown in FIG. 4, the manufacturing device forms a resist pattern RP1 on the light shielding film 17. The resist pattern RP1 has a shape that covers the OPB section 2 and exposes the pixel section 1. Next, the manufacturing device dry-etches the light shielding film 17 by using the resist pattern RP1 as a mask. As a result, as shown in FIG. 5, the light shielding film 17 is left in the OPB section 2 and is removed from the pixel section 1. Thereafter, the manufacturing device removes the resist pattern RP1.

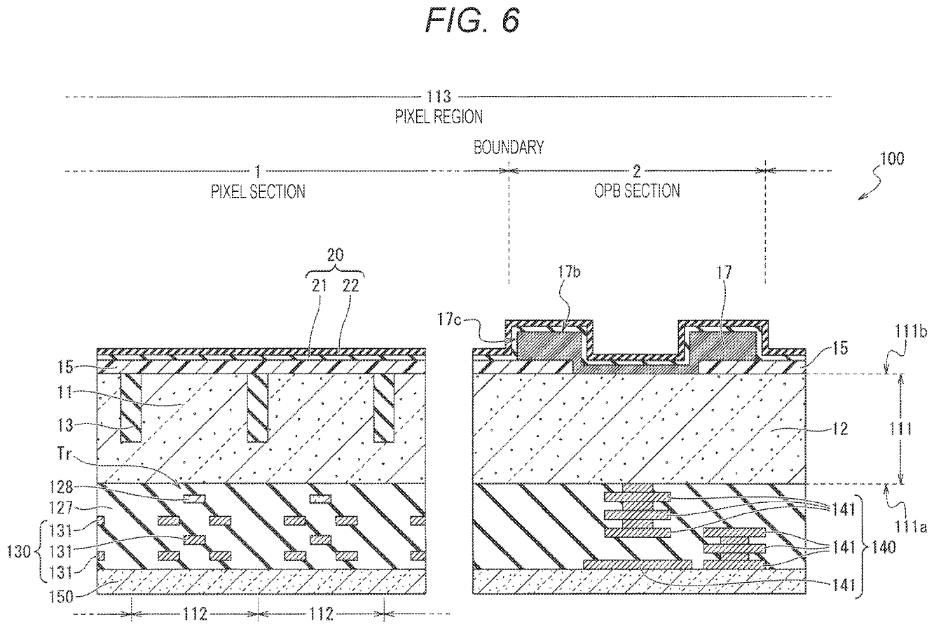

Next, as shown in FIG. 6, the manufacturing device sequentially forms the silicon oxide film 21 and the silicon nitride film 22 on the insulating film 15 so as to cover the light shielding film 17. The method of forming the above is the CVD method. The light shielding film 17 and the upper surface 17b and the side surface 17c of the light shielding film 17 are covered with the insulating film 20 including the silicon oxide film 21 and the silicon nitride film 22.

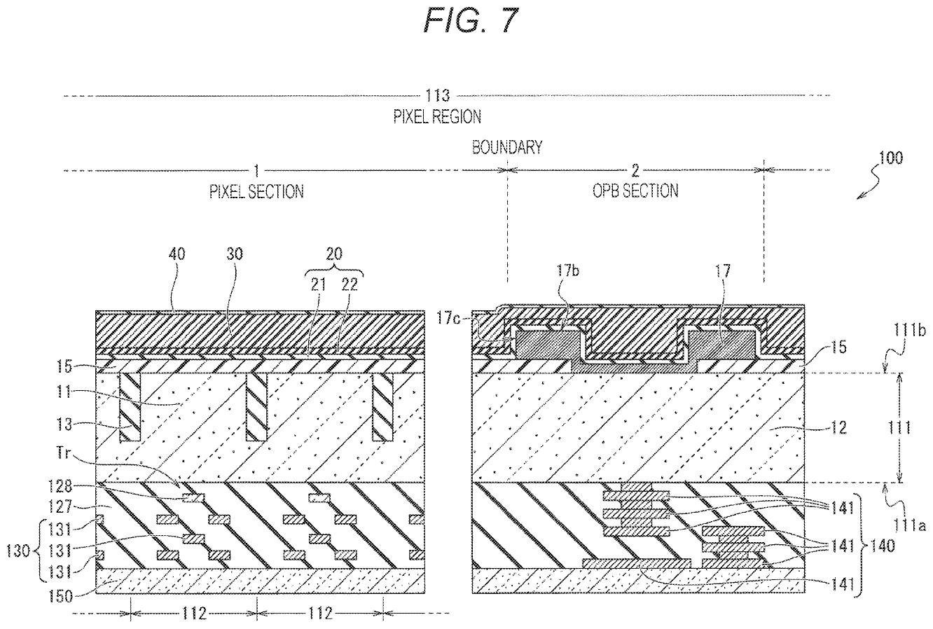

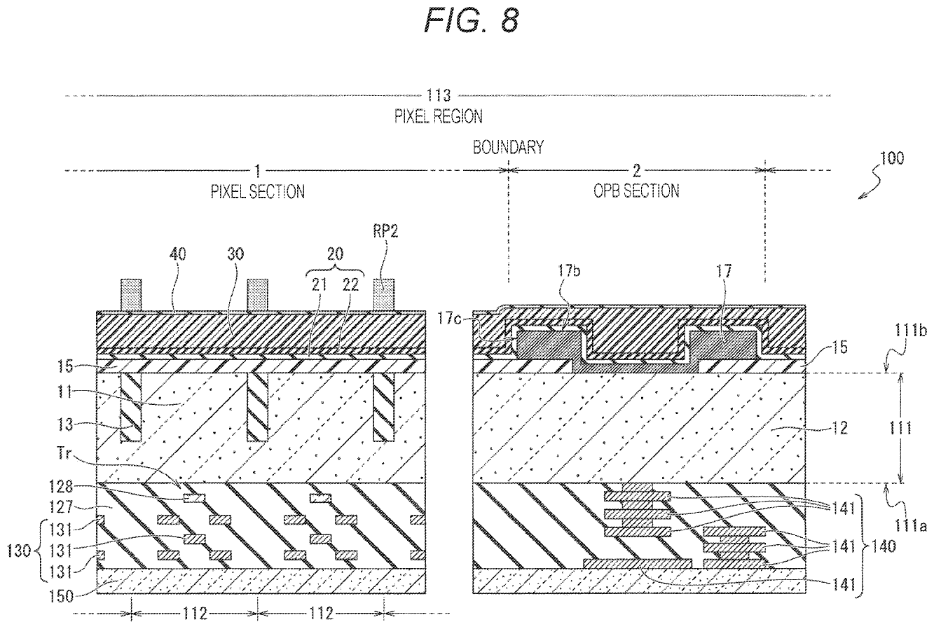

Next, as shown in FIG. 7, the manufacturing device forms the low refractive index material 30 on the insulating film 20. The low refractive index material 30 is, for example, a silicone resin. A method for forming the low refractive index material 30 is, for example, application by a spin coater. Next, the manufacturing device forms the insulating film 40 on the low refractive index material 30. The insulating film 40 is, for example, a silicon oxide film, and a method of forming the insulating film 40 is the CVD method. The insulating film 40 functions as a protective film for preventing a resist pattern RP2 (see FIG. 8) formed in the next step from directly contacting the low refractive index material 30.

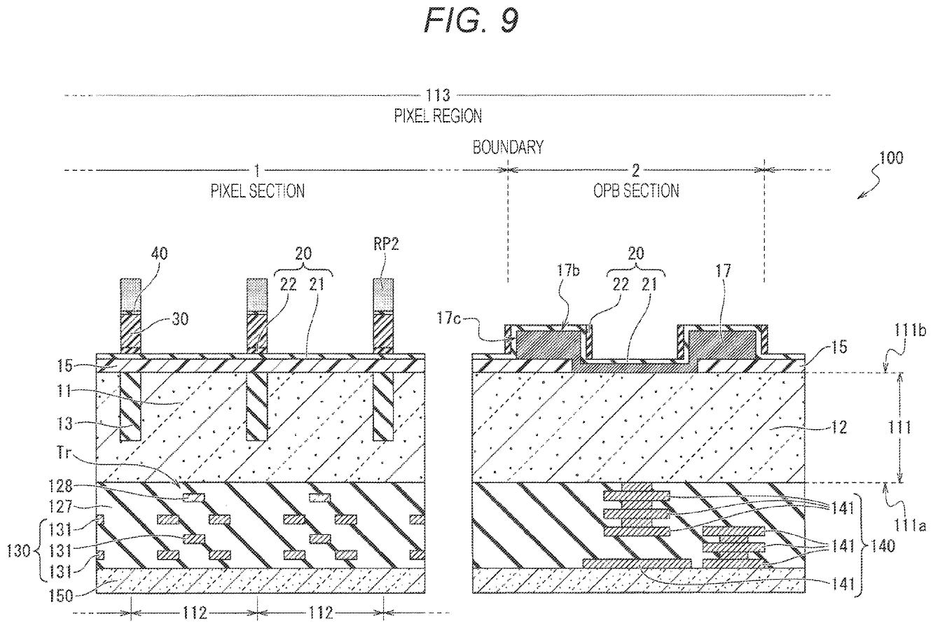

Next, as shown in FIG. 8, the manufacturing device forms the resist pattern RP2 on the insulating film 40. In the pixel section 1, the resist pattern RP2 covers an upper part of a region between the adjacent pixels 112 (for example, the element isolation layer 13), and has a shape in which the upper part of the pixels 112 is exposed. In addition, the resist pattern RP2 has a shape that exposes the OPB section 2. Next, the manufacturing device dry-etches the insulating film 40 and the low refractive index material 30 by using the resist pattern RP2 as a mask. As a result, as shown in FIG. 9, in the light shielding film 17, the insulating film 40 and the low refractive index material 30 are left in the upper part of the region between the adjacent pixels 112 (for example, the element isolation layer 13), and removed from the other regions. Thereafter, the manufacturing device removes the resist pattern RP2.

Note that, in a step of etching the low refractive index material 30 by using the resist pattern RP2, the silicon nitride film 22 functions as an etching stopper. In addition, the silicon nitride film 22 functioning as an etching stopper is etched and removed by using the resist pattern RP2 (or the patterned insulating film 40) as a mask. This removal is performed under a condition that an etching rate of the silicon oxide film 21 is sufficiently low with respect to the silicon nitride film 22. As a result, the low refractive index material 30 can be etched without causing etching damage such as film loss to the insulating film 15 covering the back surface 111b of the substrate 111.

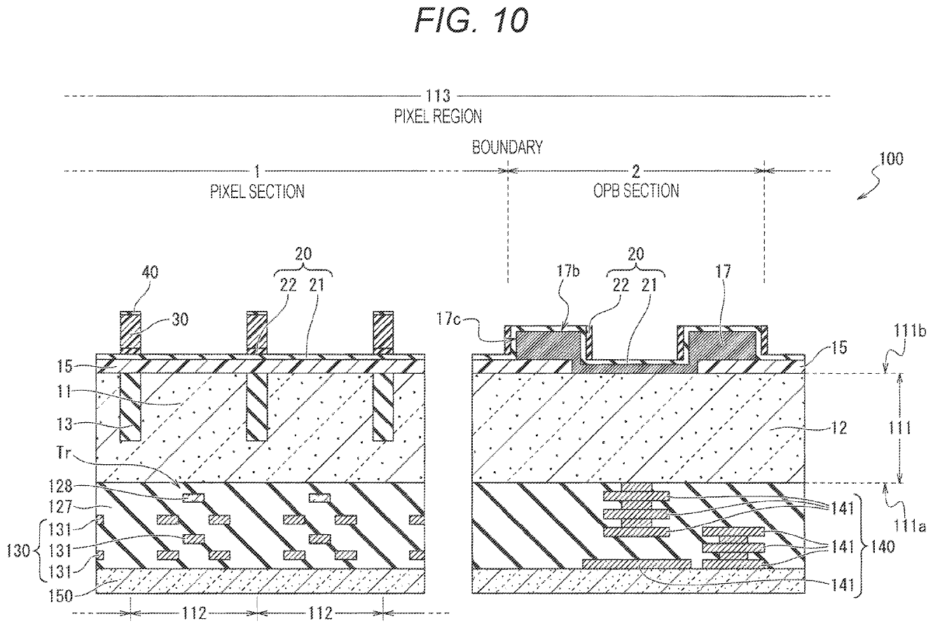

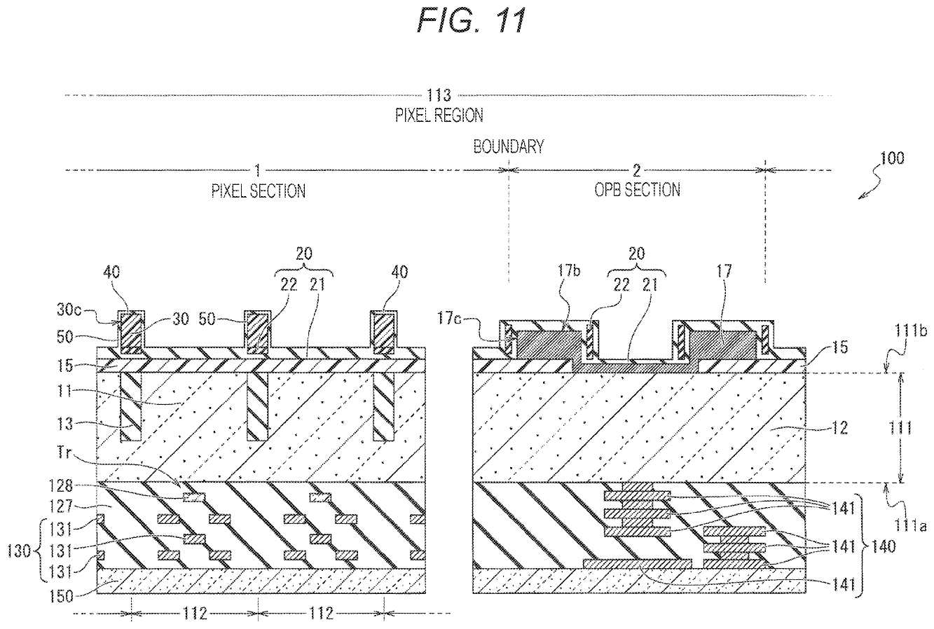

Next, in FIG. 10, the manufacturing device forms the insulating film 50 on the back surface 111b of the substrate 111. The insulating film 50 is, for example, a silicon oxide film, and a method of forming the insulating film 50 is a CVD method using tetraethoxysilane (TEOS). As a result, as shown in FIG. 11, the side surface 30c of the low refractive index material 30 left in the upper part of the region between the adjacent pixels 112 (for example, the element isolation layer 13) is covered with the insulating film 50. Furthermore, exposed portions of the insulating films 20 and 40 are also covered with the insulating film 50 (that is, the exposed portions of the insulating films 20 and 40 are thickened with the insulating film 50).

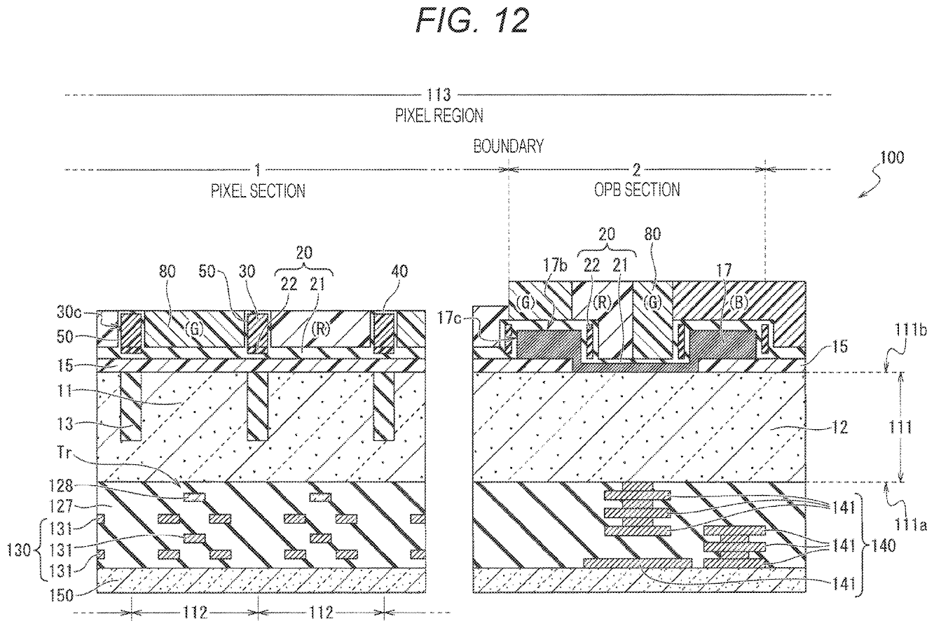

Next, as shown in FIG. 12, the manufacturing device forms the color filter 80 for every filter component of each color by using a lithography technology. Next, the manufacturing device forms the microlens 90 (see FIG. 2) above the color filter 80. For example, the manufacturing device forms the microlens 90 by forming a resin film on the color filter 80, heating and melting the formed resin film, and rounding the shape of an upper surface of the melted resin film. Through such steps, the imaging device 100 shown in FIG. 2 is completed.

### Effects of First Embodiment

As described above, the imaging device 100 according to the first embodiment of the present disclosure includes the substrate 111, the pixel section 1 that is provided on the substrate 111 and receives light from a subject, the OPB section 2 that is provided on the substrate 111 and has a light shielding film that shields light, the color filter 80 that is provided on one surface side of the substrate 111, and the low refractive index material 30 that is provided on one surface side of the substrate 111 and has a refractive index lower than the refractive index of the color filter 80. The pixel section 1 and the OPB section 2 are adjacent to each other. The low refractive index material 30 is disposed between the filter components of the color filter 80 in the pixel section 1, and is not disposed in the OPB section 2.

Thus, as compared with a case where the low refractive index material 30 is disposed on the light shielding film 17, the imaging device 100 can reduce the step Ga near the boundary between the pixel section 1 and the OPB section 2. As a result, the imaging device 100 can make a film thickness of the color filter 80 located near the boundary between the pixel section 1 and the OPB section 2 as uniform as possible. Furthermore, by reducing the step Ga described above, the imaging device 100 can suppress light transmitted through the microlens 90 and the color filter 80 of the OPB section 2 from entering the microlens 90 and the color filter 80 of the pixel 112 located near the boundary. Therefore, the imaging device 100 can reduce sensitivity unevenness of the pixel 112 located near the boundary.

Furthermore, the low refractive index material 30 is disposed between the filter components of the color filters 80. The refractive index of the low refractive index material 30 is lower than the refractive index of the color filter 80. Thus, the low refractive index material 30 can totally reflect light to be incident from one filter component (for example, the green filter component (G)) to the other filter component (for example, the red filter component (R)) adjacent to the one filter component toward the one filter component. As a result, the imaging device 100 can suppress color mixing of light incident on the color filter 80.

Furthermore, the low refractive index material 30 is not disposed at a position adjacent to the side surface 17c of the light shielding film 17 in the pixel section 1. Therefore, the color filter 80 of the pixel 112 located near the boundary can be prevented from being lifted above the step Ga by the low refractive index material 30. This configuration contributes to reduction of the step Ga.

<Modifications>

In the first embodiment described above, an aspect has been described in which the element isolation layer 13 that electrically isolates the adjacent pixels 112 from each other is provided from the back surface 111b of the substrate 111 to an intermediate position between the back surface 111b and the front surface 111a (see FIG. 2). That is, an aspect in which the element isolation layer 13 does not reach the front surface 111a of the substrate 111 is shown. However, the first embodiment of the present disclosure is not limited to this aspect.

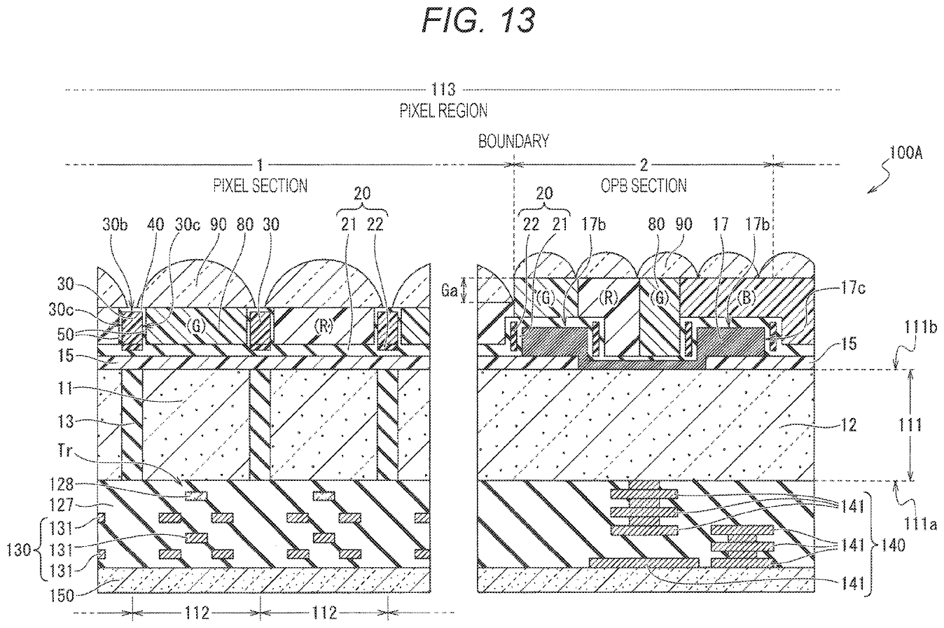

FIG. 13 is a sectional view depicting a configuration of an imaging device 100A according to a first modification of the first embodiment of the present disclosure. As shown in FIG. 13, in the imaging device 100A according to the first modification, the element isolation layer 13 is provided so as to penetrate the substrate 111 from the back surface 111b to the front surface 111a of the substrate 111. The element isolation layer 13 reaches the front surface 111a of the substrate 111. With such a configuration, the imaging device 100A can reduce the step Ga, similarly to the imaging device 100 according to the first embodiment. Therefore, the imaging device 100A can reduce the sensitivity unevenness of the pixel 112 located near the boundary.

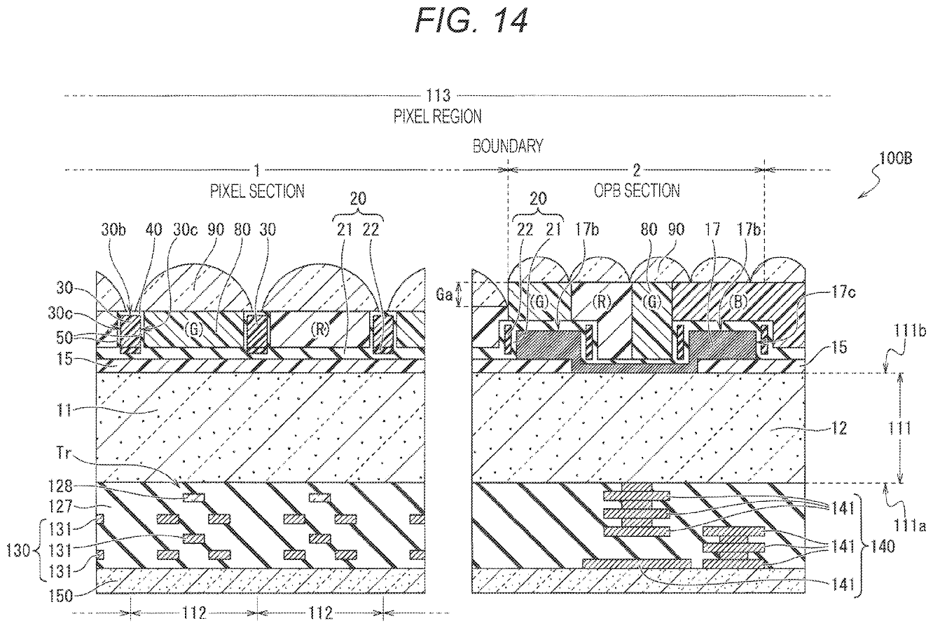

In addition, in the first embodiment of the present disclosure, the element isolation layer 13 is not required to be provided. FIG. 14 is a sectional view depicting a configuration of an imaging device 100B according to a second modification of the first embodiment of the present disclosure. As shown in FIG. 14, the imaging device 100B according to the second modification is not provided with the element isolation layer 13. With such an aspect, the imaging device 100B can reduce the step Ga, similarly to the imaging device 100 according to the first embodiment. Therefore, the imaging device 100B can reduce the sensitivity unevenness of the pixel 112 located near the boundary.

Furthermore, in the first embodiment described above, it has been described that the imaging device 100 is a back-illuminated imaging device. Alternatively, in the first embodiment of the present disclosure, the imaging device is not limited to a back-illuminated imaging device, and may be a front-illuminated imaging device.

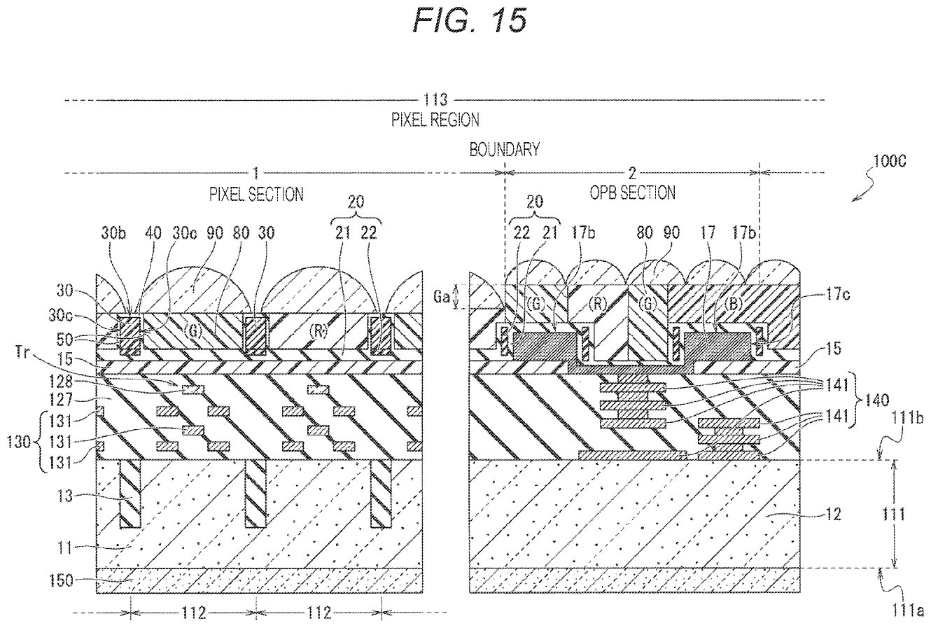

FIG. 15 is a sectional view depicting a configuration example of an imaging device 100C according to a third modification of the first embodiment of the present disclosure. The imaging device 100C according to the third modification is a front-illuminated solid-state imaging device. As shown in FIG. 15, in the imaging device 100C, the color filter 80 and the microlens 90 are disposed on the front surface 111a of the substrate 111 with the interlayer insulating film 127, the wiring layer 130, the plurality of pixel transistors Tr, and the like interposed therebetween. Light incident from the front surface 111a of the substrate 111 is condensed by the microlens 90 and is incident on the color filter 80. In the color filter 80, light having a desired wavelength is transmitted, and the transmitted light passes through the interlayer insulating film 127 and the like and is incident on the photoelectric conversion element 11 in the substrate 111. With such an aspect, the imaging device 100C can reduce the step Ga, similarly to the imaging device 100 according to the first embodiment. Therefore, the imaging device 100C can reduce the sensitivity unevenness of the pixel 112 located near the boundary.

### Second Embodiment

In the first embodiment described above, it has been described that the low refractive index material 30 is not disposed in the OPB section 2. However, an embodiment of the present disclosure is not limited to such a configuration. In an embodiment of the present disclosure, a thinned low refractive index material 30 may be disposed in the OPB section 2.

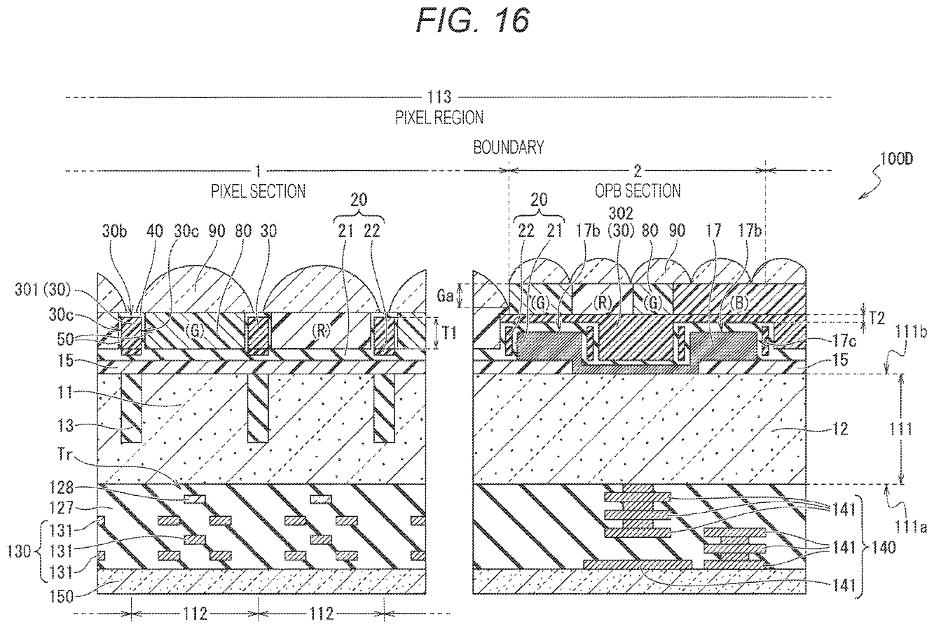

FIG. 16 is a sectional view depicting a configuration example of an imaging device 100D according to a second embodiment of the present disclosure. In the imaging device 100C according to the second embodiment, the low refractive index material 30 includes a first area 301 disposed between the filter components of the color filter 80 in the pixel section 1 and a second area 302 disposed between the light shielding film 17 and the color filter 80 in the OPB section 2. A thickness T2 of a part of the second area 302 adjacent to the pixel section 1 is thinner than a thickness T1 of the first area 301.

As compared with a case where the low refractive index material 30 is disposed on the light shielding film 17 so as to be thick, the imaging device 100D can reduce the step Ga near the boundary between the pixel section 1 and the OPB section 2. As a result, the imaging device 100D can make the film thickness of the color filter 80 located near the boundary between the pixel section 1 and the OPB section 2 as uniform as possible. Furthermore, by reducing the step Ga described above, the imaging device 100D can suppress light transmitted through the microlens 90 and the color filter 80 of the OPB section 2 from entering the microlens 90 and the color filter 80 of the pixel 112 located near the boundary. Therefore, the imaging device 100D can reduce the sensitivity unevenness of the pixel 112 located near the boundary.

### OTHER EMBODIMENTS

As described above, the present disclosure is described according to the embodiments and modifications of the embodiments, but it should not be understood that the description and drawings constituting a part of this disclosure limit the present disclosure. Various alternative embodiments, examples, and operation techniques will be apparent to those skilled in the art from this disclosure. For example, the first to third modifications of the first embodiment may be applied to the second embodiment. It is a matter of course that the present technology includes various embodiments and the like not described herein. At least one of various omissions, substitutions, or changes of the components may be made without departing from the gist of the above-described embodiments and modifications. Furthermore, the effects described herein are merely examples and are not limited, and other effects may be provided.

Note that the present disclosure can adopt the following configurations.

(1)

An imaging device includes a semiconductor layer, a pixel section that is provided in the semiconductor layer and receives light from a subject, an optical black section that is provided in the semiconductor layer and has a light shielding film that shields the light, a color filter provided on one surface side of the semiconductor layer, and a low refractive index material that is provided on one surface side of the semiconductor layer and has a refractive index lower than a refractive index of the color filter, in which the pixel section and the optical black section are adjacent to each other, and the low refractive index material is disposed between filter components of the color filter in the pixel section and is not disposed in the optical black section.

(2)

An imaging device includes a semiconductor layer, a pixel section that is provided in the semiconductor layer and receives light from a subject, an optical black section that is provided in the semiconductor layer and has a light shielding film that shields the light, a color filter provided on one surface side of the semiconductor layer, and a low refractive index material that is provided on one surface side of the semiconductor layer and has a refractive index lower than a refractive index of the color filter, in which the pixel section and the optical black section are adjacent to each other, the low refractive index material includes a first area disposed between filter components of the color filter in the pixel section and a second area disposed between the light shielding film and the color filter in the optical black section, and a thickness of a part of the second area is thinner than a thickness of the first area, the part being adjacent to the pixel section.

(3)

In the imaging device according to (1) or (2), the low refractive index material is not disposed at a position adjacent to a side surface of the light shielding film in the pixel section.

(4)

The imaging device according to any one of (1) to (3) further includes a first protective film disposed between the color filter and the light shielding film in the optical black section.

(5)

The imaging device according to any one of (1) to (4) further includes a second protective film disposed between the color filter and the low refractive index material in the pixel section.

(6)

The imaging device according to any one of (1) to (5) further includes a microlens provided on the color filter.

### REFERENCE SIGNS LIST

1 Pixel section
2 OPB section
11, 12 Photoelectric conversion element
13 Element isolation layer
20, 40, 50 Insulating film
17 Light shielding film
17b, 30b Upper surface
17c, 30c Side surface
21 Silicon oxide film
22 Silicon nitride film
30 Low refractive index material
80 Color filter
90 Microlens
100, 100A, 100B, 100C, 100D Imaging device
111 Substrate
111a Front surface
111b Back surface
112 Pixel
113 Pixel region (imaging region)
114 Vertical drive circuit
115 Column signal processing circuit
116 Horizontal drive circuit
117 Output circuit
118 Control circuit
119 Vertical signal line
120 Horizontal signal line
127 Interlayer insulating film
128 Gate electrode
130, 140 Wiring layer
131, 141 Wiring
150 Support substrate
301 First area
302 Second area
B Blue filter component
G Green filter component
Ga Step
H15 Opening
R Red filter component
RP1, RP2 Resist pattern
Tr Pixel transistor

What is claimed is:

1. An imaging device comprising:
a semiconductor layer;
a pixel section that is provided in the semiconductor layer and receives light from a subject;
an optical black section that is provided in the semiconductor layer and has a light shielding film that shields the light;
a color filter provided on one surface side of the semiconductor layer; and
a low refractive index material that is provided on one surface side of the semiconductor layer and has a refractive index lower than a refractive index of the color filter, wherein
the pixel section and the optical black section are adjacent to each other, and
the low refractive index material is disposed between filter components of the color filter in the pixel section and is not disposed in the optical black section.

2. An imaging device, comprising:
a semiconductor layer;
a pixel section that is provided in the semiconductor layer and receives light from a subject;
an optical black section that is provided in the semiconductor layer and has a light shielding film that shields the light;
a color filter provided on one surface side of the semiconductor layer; and
a low refractive index material that is provided on one surface side of the semiconductor layer and has a refractive index lower than a refractive index of the color filter, wherein
the pixel section and the optical black section are adjacent to each other,
the low refractive index material includes a first area disposed between filter components of the color filter in the pixel section and a second area disposed between the light shielding film and the color filter in the optical black section, and
a thickness of a part of the second area is thinner than a thickness of the first area, the part being adjacent to the pixel section.

3. The imaging device according to claim 1, wherein the low refractive index material is not disposed at a position adjacent to a side surface of the light shielding film in the pixel section.

4. The imaging device according to claim 1, further comprising a first protective film disposed between the color filter and the light shielding film in the optical black section.

5. The imaging device according to claim 1, further comprising a second protective film disposed between the color filter and the low refractive index material in the pixel section.

6. The imaging device according to claim 1, further comprising a microlens provided on the color filter.

7. The imaging device according to claim 2, wherein the low refractive index material is not disposed at a position adjacent to a side surface of the light shielding film in the pixel section.

8. The imaging device according to claim 2, further comprising a first protective film disposed between the color filter and the light shielding film in the optical black section.

9. The imaging device according to claim 2, further comprising a second protective film disposed between the color filter and the low refractive index material in the pixel section.

10. The imaging device according to claim 2, further comprising a microlens provided on the color filter.
